(19) United States
(12) Patent Application Publication
(10) Pub. No.: US 2013/0073108 A1
(43) Pub. Date: Mar. 21, 2013

(54) SYSTEM AND METHOD FOR REAL-TIME MONITORING OF POWER SYSTEM

(71) Applicant: Amol Rajaram Kolwalkar, Bangalore (IN)

(72) Inventor: Amol Rajaram Kolwalkar, Bangalore (IN)

(73) Assignee: GENERAL ELECTRIC COMPANY, SCHENECTADY, NY (US)

(21) Appl. No.: 13/238,051

(22) Filed: Sep. 21, 2011

(51) Int. Cl. G06F 1/28; G06F 19/00; G01R 21/06

(52) U.S. Cl. 700/298; 702/64; 702/60

(57) ABSTRACT

A real-time distributed wide area monitoring system is presented. The real-time distributed wide area monitoring system includes a plurality of phasor measurement units that measure respective synchronized phasor data of voltages and currents. The real-time distributed wide area monitoring system further includes a plurality of processing subsystems distributed in a power system, wherein at least one of the plurality of processing subsystems is configured to receive a subset of the respective synchronized phasor data, process the received subset of the respective synchronized phasor data to determine respective system parameters, wherein the plurality of processing subsystems are time synchronized.

### BACKGROUND

An electric power system typically includes a power transmission and/or power distribution network interconnecting geographically separated regions, and a plurality of power transmission and distribution substations. The substations include equipment for transforming voltages and for switching connections between individual lines of the power system. Power generation and load flow to consumers is managed by a central Energy Management System (EMS) and/or supervised by a Supervisory Control And Data Acquisition (SCADA) system. The electric power system may also include multiple phasor measurement units (PMUs). Typically these PMUs are distributed over a large geographic area, i.e. over tens to hundreds of kilometers. These PMUs generate synchronized phasor measurements or snapshots collected across the electric power system. The phasor measurements are time-stamped complex values (amplitude and phase) of local electric quantities, such as, currents, voltages and load flows.

Each of the PMUs may forward respective phasor measurements to a central processing system. The central processing system monitors the power system based upon the phasor measurements. Since the PMUs are distributed over large geographical areas, the PMUs transmit the phasor measurements across large distances to the central processing system. The transmission of phasor measurements to the central processing system results in excess utilization of communication bandwidth and time delays. For these and other reasons, there is a need for embodiments of the present invention.

### BRIEF DESCRIPTION

A real-time distributed wide area monitoring system is presented. The system includes a plurality of phasor measurement units that measure respective synchronized phasor data of voltages and currents, a plurality of processing subsystems distributed in a power system, wherein at least one of the plurality of processing subsystems is configured to receive a subset of the respective synchronized phasor data, process the received subset of the respective synchronized phasor data to determine respective system parameters, wherein the plurality of processing subsystems are time synchronized.

A real-time distributed wide area monitoring system is presented. The system includes a plurality of phasor measurement units that measure respective synchronized phasor data of voltages and currents, a plurality of phasor data concentrators distributed in a power transmission and distribution network, wherein at least one of the plurality of phasor data concentrators is configured to receive a subset of the respective synchronized phasor data from at least one of the plurality of phasor measurement units that is located in a local area network or a neighboring network of a receiving processing subsystem, process the received subset of the respective synchronized phasor data by executing at least one power system application to determine respective system parameters, determine a remedial action based upon the system parameters, and transmit control signals for execution of the remedial action to a control device, wherein the plurality of phasor data concentrators are time synchronized.

A power system is presented. The power system includes a plurality of phasor measurement units that measure respective synchronized phasor data of voltages and currents, a plurality of phasor data concentrators distributed in the power system, wherein at least one of the plurality of phasor data concentrators is configured to receive a subset of the respective synchronized phasor data, process the received subset of the respective synchronized phasor data by executing at least one power system application to determine respective system parameters, a central processing subsystem that is configured to receive one or more of the respective system parameters, process the received one or more of the respective system parameters to determine a remedial action; and transmit control signals to a control device for execution of the remedial action, wherein the plurality of phasor data concentrators are time synchronized.

A method for real-time distributed wide area monitoring of a power system is presented. The method includes the steps of measuring respective synchronized phasor data of voltages and currents by a plurality of phasor measurement units, receiving a subset of the respective synchronized phasor data by a plurality of processing subsystems, and processing the received subset of the respective synchronized phasor data to determine respective system parameters by the plurality of processing subsystems, wherein the plurality of processing subsystems are time synchronized.

### DRAWINGS

These and other features and aspects of embodiments of the present invention will become better understood when the following detailed description is read with reference to the accompanying drawings in which like characters represent like parts throughout the drawings, wherein:

FIG. 1 is a block diagram of an exemplary real-time distributed wide area power monitoring system that monitors and controls a power system in real-time, in accordance with an embodiment of the present system;

FIG. 2 is a block diagram of an exemplary power system including an exemplary distributed wide area monitoring system that monitors and controls a power system in real time, in accordance with an embodiment of the present system; and

FIG. 3 is a flowchart representing an exemplary method for real-time distributed wide area monitoring and control of a power system, in accordance with aspects of the present techniques.

### DETAILED DESCRIPTION

As discussed in detail below, embodiments of the present systems and techniques include a distributed wide area monitoring system that monitors and controls a power system in real time. The distributed wide area monitoring system includes a plurality of phasor measurements units (PMUs) and a plurality of processing subsystems. In one embodiment, the plurality of processing subsystems are phasor data concentrators. The PMUs measure synchronized phasor data at respective locations in the power system. The synchronized phasor data, for example, includes phasor currents and phasor voltages. The processing subsystems receive synchronized phasor data from at least one of the PMUs. Particularly, the processing subsystems receive the synchronized phasor data from at least one of the PMUs that is located in a local area network or a neighboring network of the receiving processing subsystems. The processing subsystems determine one or more respective system parameters by processing the received synchronized phasor data. As used herein, the term “system parameters” may be used to refer to parameters that are used to determine the state, stability and faults in a power system. The determination of the system parameters locally by the processing subsystems result in reduced consumption of communication bandwidth, and reduces time delays.

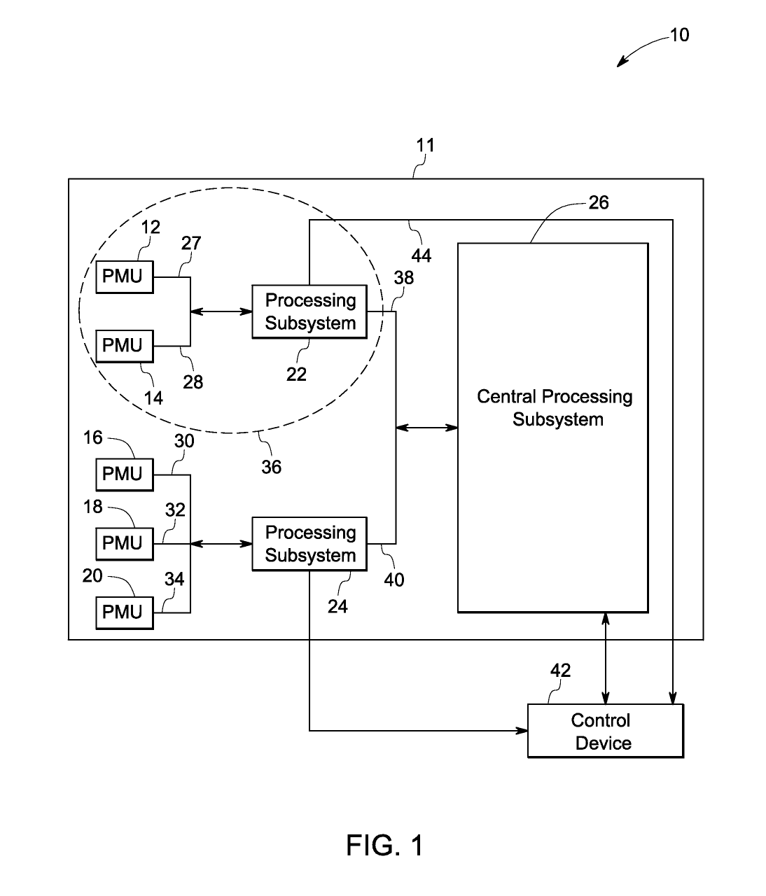

FIG. 1 is a block diagram of a distributed wide area monitoring system (DWAMS) 11 that monitors and controls a power system 10 in real-time. It may be noted that the power system 10 may include a power generation network, a power transmission network and a power distribution network, a transmission substation, a distribution substation and other devices. However, for ease of understanding, the power generation network, power transmission network and power distribution network, transmission substation, distribution substation and other devices are not shown in FIG. 1. As shown in the presently contemplated configuration, the DWAMS 11 includes a plurality of phasor measurement units (PMUs) 12, 14, 16, 18, 20, a plurality of processing subsystems 22, 24 and a central processing subsystem 26. The PMUs 12, 14, 16, 18, 20 may be a protective relay, an intelligent electronic device, a remote terminal unit, or combinations thereof. In one embodiment, the PMUs 12, 14, 16, 18, 20 may be located over large geographical areas in the power system 10. The PMUs 12, 14, 16, 18, 20 measure synchronized phasor data at respective locations in the power system 10. The synchronized phasor data, for example, may include phasor voltages and phasor currents. As shown in FIG. 1, the PMU 12 measures synchronized phasor data 27 and the PMU 14 measures synchronized phasor data 28. Similarly, the PMU 16 measures synchronized phasor data 30, the PMU 18 measures synchronized phasor data 32 and the PMU 20 measures synchronized phasor data 34. Each of the PMUs 12, 14, 16, 18, 20 transmits respective synchronized phasor data 27, 28, 30, 32, 34 to respective processing subsystems 22, 24. Particularly, the PMUs 12, 14, 16, 18, 20 transmit respective phasor data 27, 28, 30, 32, 34 to the processing subsystems 22, 24 that are located in respective local area network or neighboring network. In the presently contemplated configuration, the PMUs 12, 14 are located in the local area network or neighboring network 36 of the processing subsystem 22. Therefore, the PMUs 12, 14 transmit respective phasor data 27, 28 to the processing subsystem 22. Similarly, the PMUs 16, 18, 20 transmit respective synchronized phasor data 30, 32, 34 to the processing subsystem 24 as the PMUs 16, 18, 20 are located in the neighboring network or local area network of the processing subsystem 24.

As previously noted, the DWAMS 11 includes the processing subsystems 22, 24. The processing subsystems 22, 24 are distributed in the power system 10 such that the processing subsystems 22, 24 are located in neighboring networks or local area networks of at least one of the PMUs 12, 14, 16, 18, 20. The processing subsystems 22, 24, for example, may be a phasor data concentrator, a data aggregator, a data concentrator, or combinations thereof. Each of the processing subsystems 22, 24 receives at least one of the synchronized phasor data 27, 28, 30, 32, 34. As shown in FIG. 1, the processing subsystem 22 receives the synchronized phasor data 27, 28, and the processing subsystem 24 receives the synchronized phasor data 30, 32, 34. The processing subsystems 22, 24 are configured to process the received synchronized phasor data 27, 28, 30, 32, 34 by executing one or more power system applications. In the presently contemplated configuration, the processing subsystem 22 processes the received synchronized phasor data 27, 28, and the processing subsystem 24 processes the received synchronized phasor data 30, 32, 34. The power system applications, for example, may include a small signal oscillation detection method, a phase estimation method, a voltage stability determination method, a dynamic stability determination method, a real-time dynamic measurement application, protection settings application, and the like.

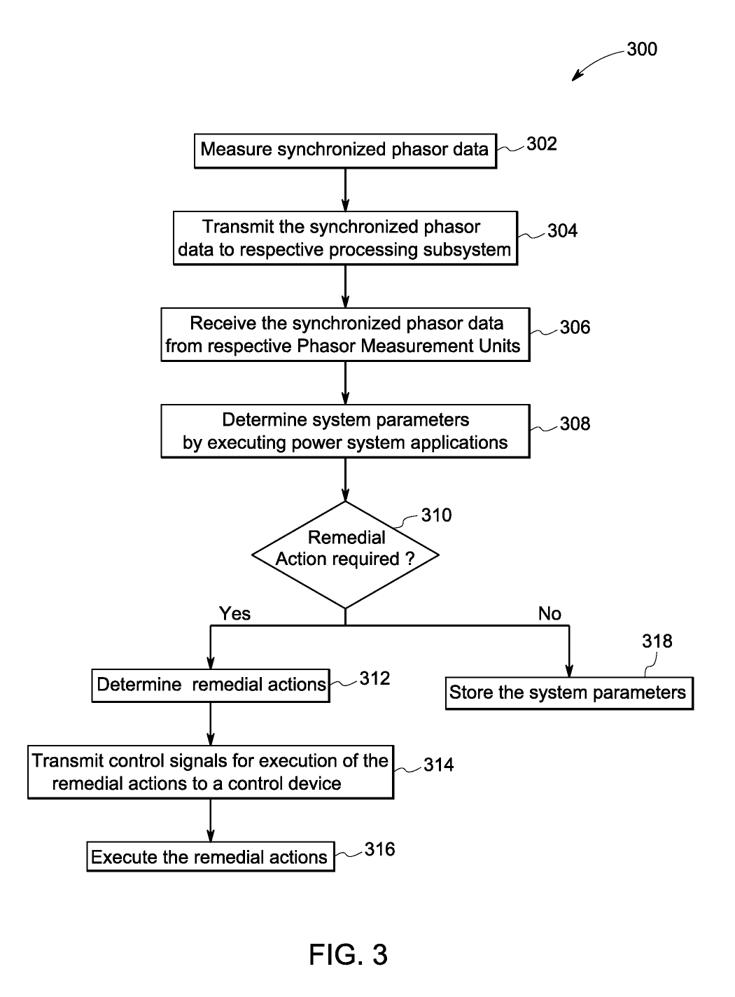

Consequent to the processing of the received synchronized phasor data 27, 28, 30, 32, 34, system parameters 38, 40 are determined. Particularly, the processing subsystem 22 determines system parameters 38, and the processing subsystem 24 determines system parameters 40. Furthermore, the processing subsystems 22, 24 may determine remedial actions based upon the system parameters. The determination of the remedial actions will be explained with an example in FIG. 3. The remedial actions, for example, may include load shedding, generator Re-Dispatch, system reconfiguration controls, a dynamic control of a device, and the like. Subsequent to the determination of the remedial actions, the processing subsystems 22, 24 may transmit control signals for the execution of the remedial actions. The control signals, for example, may be transmitted to a control device 42. In the presently contemplated configuration, the processing subsystem 22 determines at least one of the remedial actions, and transmits control signals 44 to the control device 42. The control device, for example, may include a protection device, a flexible AC transmission device, a generator control device, and the like. In certain embodiments, the processing subsystems 22, 24 may transmit the system parameters to the central processing subsystem 26. The central processing subsystem 26 may determine at least one remedial action based upon the system parameters. Additionally, the central processing subsystem 26 may transmit control signals to the control device 42 for execution of the remedial actions.

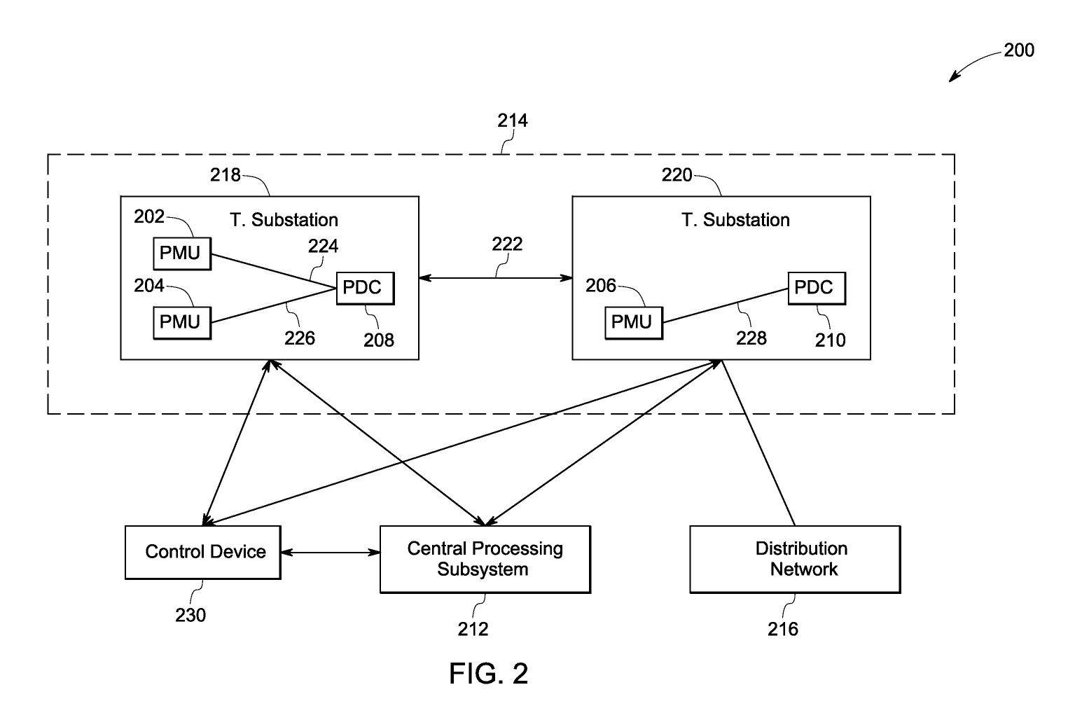

FIG. 2 is a block diagram of an exemplary power system 200 including an exemplary distributed wide area monitoring system to monitor and control the power system 200 in real-time. In the presently contemplated configuration, the distributed wide area monitoring system includes a plurality of PMUs 202, 204, 206, a plurality phasor data concentrators (PDCs) 208, 210 and a central processing subsystem 212. The PDCs 208, 210, for example, may be similar to the processing subsystems 22, 24 in FIG. 1. Particularly, the PDCs 208, 210 may perform the functions of the processing subsystems 22, 24 described with reference to FIG. 1.

Furthermore, the power system 200 includes a transmission network 214 and a distribution network 216. As shown in FIG. 2, the transmission network 214 includes multiple transmission substations 218, 220. The transmission substations 218, 220 are electrically and communicatively coupled to each other by a link 222. In the presently contemplated configuration, the transmission substation 218 includes the PMUs 202, 204, and the transmission substation 220 includes the PMU 206. Additionally the transmission substation 218 includes the PDC 208, and the transmission substation 220 includes the PDC 210. It may be noted that though the PDCs 208, 210 are shown in the substations 218, 220, the PDCs 208, 210 may be located in a local area network or a neighboring network of the PMUs 202, 204, 206.

Each of the PMUs 202, 204, 206 measures synchronized phasor data at respective locations. In the presently contemplated configuration, the PMU 202 measures synchronized phasor data 224, the PMU 204 measures synchronized phasor data 226 and the PMU 208 measures synchronized phasor data 228. As previously noted, the synchronized phasor data 224, 226, 228 includes phasor currents and phasor voltages. The PMUs 202, 204, 206 transmit respective synchronized phasor data 224, 226, 228 to at least one of the PDCs 208, 210 that are located in a local area network or a neighboring network of the PMUs 202, 204, 206. In the presently contemplated configuration, the PDC 208 receives the synchronized phasor data 224, 226 from the PMUs 202, 204. Furthermore, the PDC 210 receives the synchronized phasor data 228 from the PMU 206.

In one embodiment, the PDCs 208, 210 are configured to process the received synchronized phasor data 224, 226, 228 to determine system parameters. Particularly, the PDC 208 determines system parameters by processing the received synchronized phasor data 224, 226. Additionally, the PDC 210 determines the system parameters by processing the received synchronized phasor data 228. As previously noted, the system parameters may include a voltage stability index, a voltage stability margin, state of the transmission and distribution network, stability of the transmission and distribution network, oscillations in the transmission and distribution network, local oscillatory modes, faults in respective substations, or the like. In one embodiment, the PDCs 208, 210 may process the synchronized phasor data 24, 26, 28 by executing at least one power system application. Particularly, the PDCs 208, 210 determine the system parameters by executing the power system applications. The power system applications, for example, may include a small signal oscillation detection method, a phase estimation method, a voltage stability determination method, a dynamic stability determination method, a protection settings application, or the like.

In certain embodiments, the PDCs 208, 210 may determine remedial actions based upon the system parameters. Furthermore, the PDCs 208, 210 may transmit control signals to a control device 230 for execution of the remedial actions. As used herein, the term “remedial actions” may be used to refer to actions that may be executed to eliminate faults or retain the stability in a power system. The remedial actions, for example, may include load shedding, generator Re-Dispatch, system reconfiguration controls, a dynamic control of a device, and the like. Additionally, the PDCs 208, 210 may transmit control signals to a control device 230 for execution of the remedial actions. In certain embodiments, the PDCs 208, 210 may transmit the system parameters to the central processing subsystem 212. The central processing subsystem 212 may determine remedial actions based upon the system parameters. The central processing subsystem 212 may determine the remedial actions by execution of at least one power system application.

FIG. 3 is a flowchart representing an exemplary method 300 for distributed wide area monitoring and control of the power system 10 in FIG. 1, in accordance with aspects of the present techniques. At step 302, synchronized phasor data may be measured by a plurality of PMUs. The synchronized phasor data, for example, may include the synchronized phasor data 27, 28, 30, 32, 34, 224, 226, 228 that are measured by the PMUs 12, 14, 16, 18, 20, 202, 204, 206, respectively. (See FIG. 1 and FIG. 2). Subsequently, at step 304, the PMUs may transmit the synchronized phasor data to at least one processing subsystem. Each PMU transmits respective synchronized phasor data to a processing subsystem that is located in a local area network or a neighboring network of the PMU. As previously noted, the processing subsystem may be a phasor data concentrator, a data aggregator, a data concentrator, or combinations thereof.

At step 306, each of the at least one processing subsystem receives the synchronized phasor data. Particularly, each processing subsystem receives synchronized phasor data from PMUs that are located in a local area network or a neighboring network of the processing subsystem. Furthermore, at step 308, each of the processing subsystems determines system parameters by processing the received synchronized phasor data. The processing subsystems process the synchronized phasor data by executing power system applications. Since the system parameters are determined by the processing subsystems that are located in the local area network or neighboring network of the PMUs, the system parameters are determined in real-time. Furthermore, at step 310, it is determined whether remedial actions are required. The requirement of remedial actions may be determined based upon the system parameters. For example, when the system parameters show that a local area network of a processing subsystem is unstable, the requirement of remedial actions may be declared at step 310. Similarly, when the system parameters show that voltage stability index at a point in a local area network is beyond a determined threshold, then a requirement of remedial actions may be declared.

At step 310, when it is determined that remedial actions are required, the control may be transferred to step 312. At step 312, one or more remedial actions may be determined. The remedial actions, for example may be determined by the processing subsystems, such as, the processing subsystems 22, 24, 208, 210. (See FIG. 1 and FIG. 2). In one embodiment, the remedial actions may be determined by the central processing subsystem 26, 212. In an embodiment, when the remedial actions are determined by the central processing subsystem 26, 212, the system parameters may be transmitted to the central processing subsystem 26, 212 before determination of the remedial actions. Furthermore, at step 314, control signals may be transmitted for execution of the remedial actions. The control signals, for example, may be transmitted to a control device, such as, the control device 42, 230. The control device may execute the remedial actions at step 316. The execution of the remedial actions results in real-time monitoring and control of a power system, such as, the power system 10, 200. Turning back to step 310, when it is determined that the remedial actions are not required, the control may be transferred to step 318. At step 318, the system parameters may be stored in a data repository by each of the processing subsystems 22, 24.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed as new and desired to be protected by Letters Patent of the United States is:

1. A real-time distributed wide area monitoring system, comprising:
a plurality of phasor measurement units that measure respective synchronized phasor data of voltages and currents;
a plurality of processing subsystems distributed in a power system, wherein at least one of the plurality of processing subsystems is configured to:
receive a subset of the respective synchronized phasor data;
process the received subset of the respective synchronized phasor data to determine respective system parameters,
wherein the plurality of processing subsystems are time synchronized.

2. The real-time distributed wide area monitoring system of claim 1, wherein a processing subsystem in the plurality of processing subsystems receives a subset of synchronized phasor data from at least one phasor measurement unit that is located in a local area network or a neighboring network of the processing subsystem.

3. The real-time distributed wide area monitoring system of claim 1, wherein the plurality of phasor measurement units comprises a protective relay, an intelligent electronic device, a remote terminal unit, or combinations thereof.

4. The real-time distributed wide area monitoring system of claim 1, wherein the plurality of processing subsystems comprises a phasor data concentrator, a data aggregator, a data concentrator, or combinations thereof.

5. The real-time distributed wide area monitoring system of claim 4, wherein the phasor data concentrator executes at least one power system application to determine the respective system parameters.

6. The real-time distributed wide area monitoring system of claim 1, wherein at least one of the plurality of processing subsystems processes the received subset of the respective synchronized phasor data by executing at least one power system application.

7. The real-time distributed wide area monitoring system of claim 6, wherein the at least one power system application comprises a small signal oscillation detection method, a phase estimation method, a voltage stability determination method, a dynamic stability determination method, a protection settings application, or combinations thereof.

8. The real-time distributed wide area monitoring system of claim 1, wherein the system parameters comprise a voltage stability index, a voltage stability margin, state of a transmission and distribution network, stability of the transmission and distribution network, oscillations in the transmission and distribution network, local oscillatory modes and faults in respective substations.

9. The real-time distributed wide area monitoring system of claim 1, wherein each of the plurality of processing subsystems is configured to transmit one or more of the respective system parameters to a central processing subsystem.

10. The real-time distributed wide area monitoring system of claim 9, further comprising the central processing subsystem that is configured to:
receive the one or more of the respective system parameters;
process the received one or more of the respective system parameters to determine a remedial action; and
transmit control signals to a control device for execution of the remedial action.

11. The real-time distributed wide area monitoring system of claim 10, wherein the remedial action comprises load shedding, generator Re-Dispatch, system reconfiguration controls, a dynamic control of a device, or combinations thereof.

12. The real-time distributed wide area monitoring system of claim 10, wherein the control device, comprises a protection device, a flexible AC transmission device, a generator control device, or combinations thereof.

13. A real-time distributed wide area monitoring system, comprising:
a plurality of phasor measurement units that measure respective synchronized phasor data of voltages and currents;
a plurality of phasor data concentrators distributed in a power transmission and distribution network, wherein at least one of the plurality of phasor data concentrators is configured to:
receive a subset of the respective synchronized phasor data from at least one of the plurality of phasor measurement units that is located in a local area network or a neighboring network of a receiving phasor data concentrator;
process the received subset of the respective synchronized phasor data by executing at least one power system application to determine respective system parameters;
determine a remedial action based upon the system parameters; and
transmit control signals for execution of the remedial action to a control device,
wherein the plurality of phasor data concentrators are time synchronized.

14. A power system, comprising:
a plurality of phasor measurement units that measure respective synchronized phasor data of voltages and currents;
a plurality of phasor data concentrators distributed in the power system, wherein at least one of the plurality of phasor data concentrators is configured to:
receive a subset of the respective synchronized phasor data;
process the received subset of the respective synchronized phasor data by executing at least one power system application to determine respective system parameters;
a central processing subsystem that is configured to:
receive one or more of the respective system parameters;
process the received one or more of the respective system parameters to determine a remedial action; and
transmit control signals to a control device for execution of the remedial action,
wherein the plurality of phasor data concentrators are time synchronized.

15. A method for real-time distributed wide area monitoring of a power system, comprising:
measuring respective synchronized phasor data of voltages and currents by a plurality of phasor measurement units;
receiving a subset of the respective synchronized phasor data by a plurality of processing subsystems; and
processing the received subset of the respective synchronized phasor data to determine respective system parameters by the plurality of processing subsystems,
wherein the plurality of processing subsystems are time synchronized.

16. The method of claim 15, wherein processing the received synchronized phasor data comprises executing at least one power system application by one or more of the plurality of processing subsystems.

17. The method of claim 15, further comprising:
processing the respective system parameters to determine a remedial action by the plurality of processing subsystems; and
transmitting control signals to a control device for execution of the remedial action.
